(19) United States
(12) Patent Application Publication
(10) Pub. No.: US 2012/0262885 A1
(43) Pub. Date: Oct. 18, 2012

(54) SIGNAL TRANSFER CIRCUIT

(75) Inventors: Yasuhiro IKEDA, Fujisawa (JP); Yutaka Uematsu, Kawasaki (JP); Satoshi Muraoka, Yokohama (JP)

(73) Assignee: Hitachi, Ltd.

(21) Appl. No.: 13/358,540

(22) Filed: Jan. 26, 2012

(30) Foreign Application Priority Data
Apr. 15, 2011 (JP) 2011-091408

(51) Int. Cl. H05K 1/18

(52) U.S. Cl. 361/748

(57) ABSTRACT

Provided is a signal transfer circuit which uses a low cost circuit board with a high packing density but is capable of reducing a crosstalk noise between signal lines and also reducing a reflection noise due to a stub. A signal transfer circuit of the present invention is configured such that lead terminals of electronic components and through-hole vias are connected to each other by surface wirings, respectively, to allow no branching from the middle of the through-hole vias. Further, first wirings connecting a first electronic component are each arranged between a corresponding pair of second wirings connecting a second electronic component, and signals are transmitted through the first wirings and the second wirings by interleaved transmission.

### BACKGROUND OF THE INVENTION

1. Field of the Invention

The present invention relates to a signal transfer circuit formed on a board on which electronic components are mounted.

2. Description of the Related Art

In recent years, there has been an increasing demand for low cost, high speed, and large capacity computers, storage devices, and the like. In some of these devices, memories with inexpensive semiconductor packages (such as TSOP: Thin Small Outline Package) are mounted highly densely in order to achieve high speed signal processing at low cost.

In such a configuration, the gap between signal lines is narrow, and a crosstalk noise therefore increases. Moreover, in low cost boards, vias are formed as through-hole vias penetrating through the boards, and stubs (signal paths branching off from the middle of the vias) are likely to be generated. Signal reflection caused by the stubs affects only to a small extent when the signal transfer rate is low. However, when the signal transfer rate is high, signal quality degradation attributable to reflection noises caused by the stubs is prominent.

As a technique to reduce a crosstalk noise between signal lines, Patent Document 1 listed below describes a method in which signals varying at different timings are transmitted through different buses, respectively.

Patent Document 2 listed below describes a circuit configuration in which a memory controller and memories are connected to each other in a stubless manner.
Patent Document 1: Japanese Patent Application Publication No. 2003-7823
Patent Document 2: Japanese Patent Application Publication No. 2004-62725

### SUMMARY OF THE INVENTION

To suppress the crosstalk noise generated between the signal lines on the circuit board, it is desirable to increase the pitch at which the signal lines are arranged. As a possible method therefor, internal wirings buried inside the circuit board may be used as the signal lines. The internal wirings are provided by connecting, inside the circuit board, signal lines to vias provided extending in the thickness direction of the board.

Note that circuit boards on which inexpensive semiconductor packages are mounted for cost reduction employ through-hole vias penetrating through the boards in view of lowering the cost of forming the vias. For this reason, connecting the internal wirings to the vias at the middle thereof creates branching paths therefrom and thereby forms stubs.

The present invention has been made to solve the above problem, and provides a signal transfer circuit which uses a low cost circuit board with a high packing density but is capable of reducing a crosstalk noise between signal lines and also reducing a reflection noise due to a stub.

The signal transfer circuit of the present invention is configured such that lead terminals of electronic components and through-hole vias are connected by surface wirings to allow no branching from the middle of the through-hole vias. Further, first wirings connecting a first electronic component and a transmission circuit are each arranged between a corresponding pair of second wirings connecting a second electronic component and the transmission circuit, and signals are transmitted through the first wirings and the second wirings by interleaved transmission.

With the signal transfer circuit of the present invention, no branching path is allowed from the middle of the through-hole vias, thereby suppressing a reflection noise at a stub. Moreover, the interleaved transmission of signals suppresses a crosstalk noise between the signal lines. Accordingly, it is possible to provide a signal transmission circuit which is low in cost, high in packaging density, and excellent in signal quality.

### BRIEF DESCRIPTION OF THE DRAWINGS

FIG. 1 is a configuration diagram of a signal transfer circuit 10 of Embodiment 1.

FIG. 2 is a transparent top view and a cross-sectional side view of the signal transfer circuit 10 of Embodiment 1.

FIG. 3 is a cross-sectional side view of a conventional signal transfer circuit.

FIGS. 4A and 4B are diagrams showing analysis models of the signal transfer circuits.

FIGS. 5A and 5B are diagrams showing the results of signal waveform analyses using the analysis models shown in FIGS. 4A and 4B.

FIG. 6 is a transparent top view of a signal transfer circuit 10 of Embodiment 2.

FIG. 7 is a transparent top view showing another example configuration of the signal transfer circuit 10 of Embodiment 2.

FIG. 8 is a cross-sectional side view of a signal transfer circuit 10 of Embodiment 3.

FIG. 9 is a cross-sectional side view of a signal transfer circuit 10 of Embodiment 4.

FIG. 10 is a cross-sectional side view of a signal transfer circuit 10 of Embodiment 5.

FIG. 11 is a diagram showing an example configuration of a signal transmission circuit 300 of Embodiment 6.

FIG. 12 is a configuration diagram of a signal transfer circuit 10 of Embodiment 7.

### DESCRIPTION OF THE PREFERRED EMBODIMENTS

### Embodiment 1

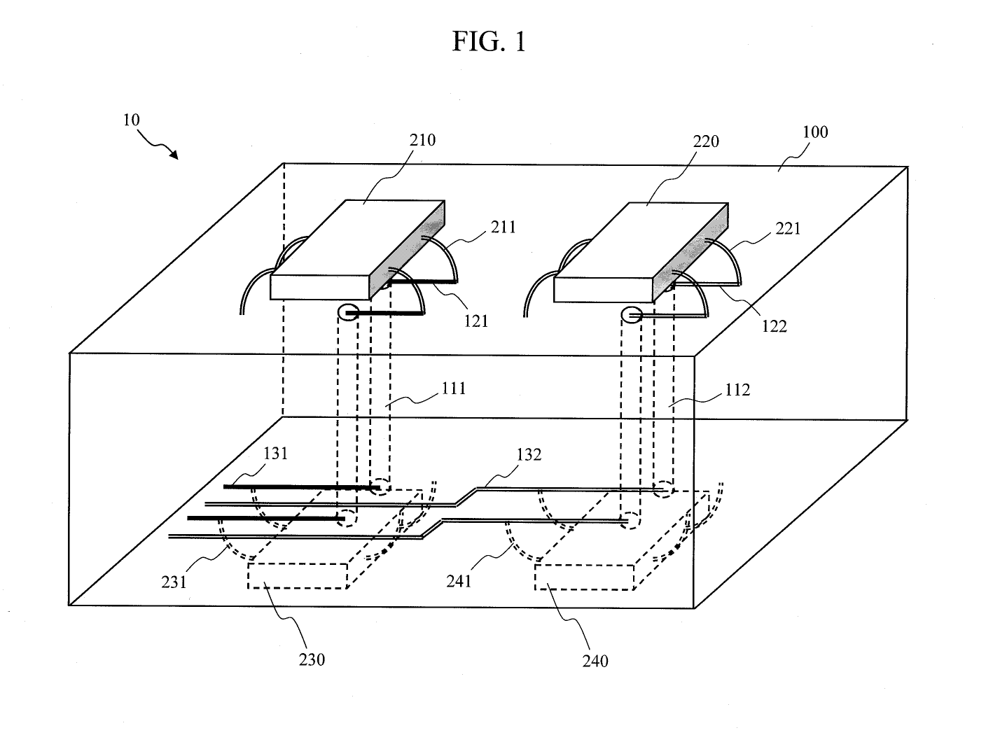

FIG. 1 is a configuration diagram of a signal transfer circuit 10 of Embodiment 1 of the present invention. The signal transfer circuit 10 includes a board 100, electronic components 210, 220, 230, and 240, through-hole vias 111 and 112, and surface wirings 121, 122, 131, and 132.

The electronic components 210 and 220 are mounted on the front surface of the board 100 and include sets of lead terminals 211 and 221, respectively. The electronic components 230 and 240 are mounted on the back surface of the board 100 and include sets of lead terminals 231 and 241, respectively. For simple description, four lead terminals are illustrated in each set.

The through-hole vias 111 and 112 penetrate through the board 100. The through-hole vias 111 are connected to the electronic component 210 through the surface wirings 121 and the lead terminals 211, respectively. The through-hole vias 112 are connected to the electronic component 220 through the surface wirings 122 and the lead terminals 221, respectively.

The electronic component 230 is connected to the through-hole vias 111 through the lead terminals 231 and the surface wirings 131, respectively. The electronic component 240 is connected to the through-hole vias 112 through the lead terminals 241 and the surface wirings 132, respectively.

The surface wirings 131 and 132 are collected at the back surface of the board 100 and connected to a signal transmission circuit 300 described later. The electronic components 210, 220, 230, and 240 are configured to receive signals from the signal transmission circuit 300 through the surface wirings 131 and 132.

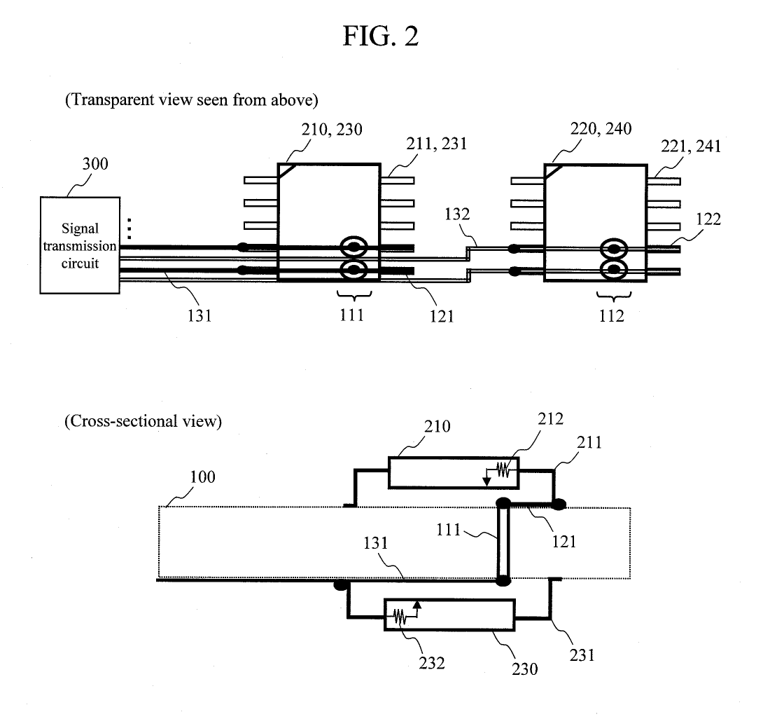

FIG. 2 is a transparent top view and a cross-sectional side view of the signal transfer circuit 10 of Embodiment 1. The transparent top view is a view of the signal transfer circuit 10 seen in a see-through manner from above. Components located at the same positions in the top view are illustrated collectively with their reference numerals shown in FIG. 1.

The surface wirings 132, which extend between the lead terminals 211 of the electronic component 210, are connected to the signal transmission circuit 300. The lead terminals 211 are connected to the surface wirings 121 and the surface wirings 131, and therefore the surface wirings 131 and 132 are arranged alternately.

Each through-hole via 111 is connected to its corresponding surface wirings 121 and 131 at the front and back surfaces of the board 100, respectively, and has no branch path at the middle thereof. Accordingly, no stub portion is created on the through-hole via 111, thereby reducing a reflection noise caused by a stub.

Signals transmitted by the signal transmission circuit 300 reach the electronic component 230 through the surface wirings 131, and further reach the electronic component 210 through the through-hole vias 111 and the surface wirings 121. The electronic components 210 and 230 include therein termination resistors 212 and 232 (e.g., ODT: On Die Termination) configured to terminate the signal lines from the signal transmission circuit 300, respectively.

The electronic components 220 and 240 and the through-hole vias 112 have the same configuration as that described above. Note that since the surface wirings 131 and 132 are arranged alternately, simple transmission of signals from the signal transmission circuit 300 causes a crosstalk noise between the surface wirings 131 and 132. To solve this, the signal transmission circuit 300 transmits signals through the surface wirings 131 and 132 by interleaved transmission. In this way, the crosstalk noise can be reduced.

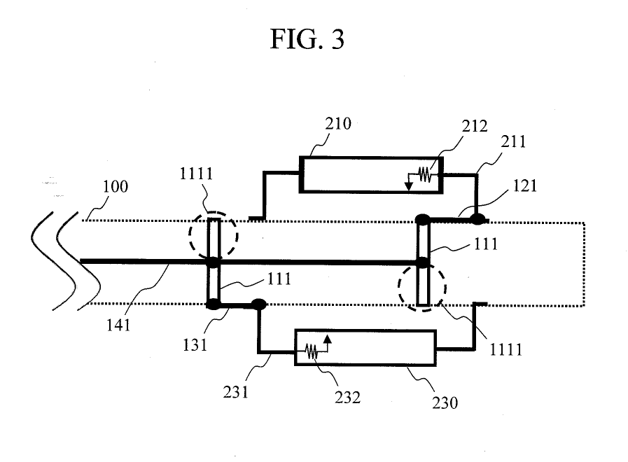

FIG. 3 is a cross-sectional side view of a conventional signal transfer circuit. This conventional configuration is shown for a comparison with the signal transfer circuit 10 of the present invention. In the conventional signal transfer circuit, internal wirings 141 buried inside a board 100 are connected to through-hole vias 111 at the middle thereof, thereby causing the through-hole vias 111 to branch off and forming stubs 1111.

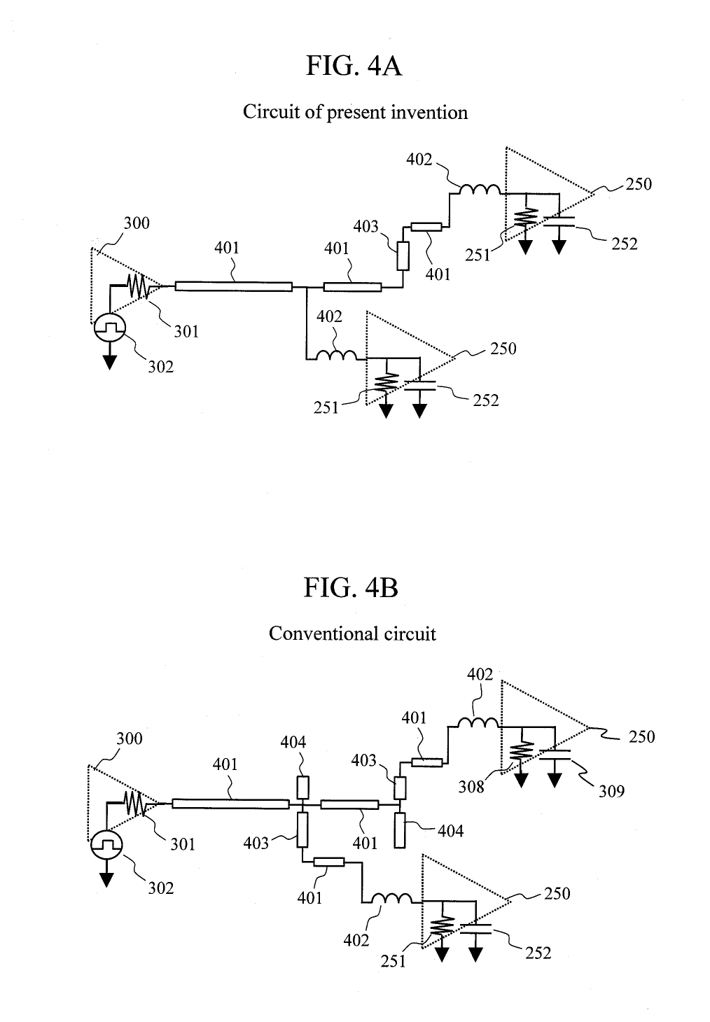

FIGS. 4A and 4B are diagrams showing analysis models of the signal transfer circuits. FIG. 4A shows the analysis model of the signal transfer circuit 10 of Embodiment 1 while FIG. 4B shows the analysis model of the convention signal transfer circuit shown in FIG. 3.

As for the signal transfer circuit 10 of Embodiment 1, the signal transmission circuit 300 can be modeled by means of a resistor 301 and a waveform generator 302. The electronic components 210 to 240 can be modeled as receiving elements 250 each including a resistor 251 and a capacitor 252. The lead terminals are modeled with inductors 402. The surface wirings are modeled with signal lines 401. The through-hole vias 111 and 112 are modeled with signal lines 403.

The conventional signal transfer circuit can be modeled in the same way, but differs from the signal transfer circuit 10 of Embodiment 1 in that the stubs 1111 are modeled with signal lines 404.

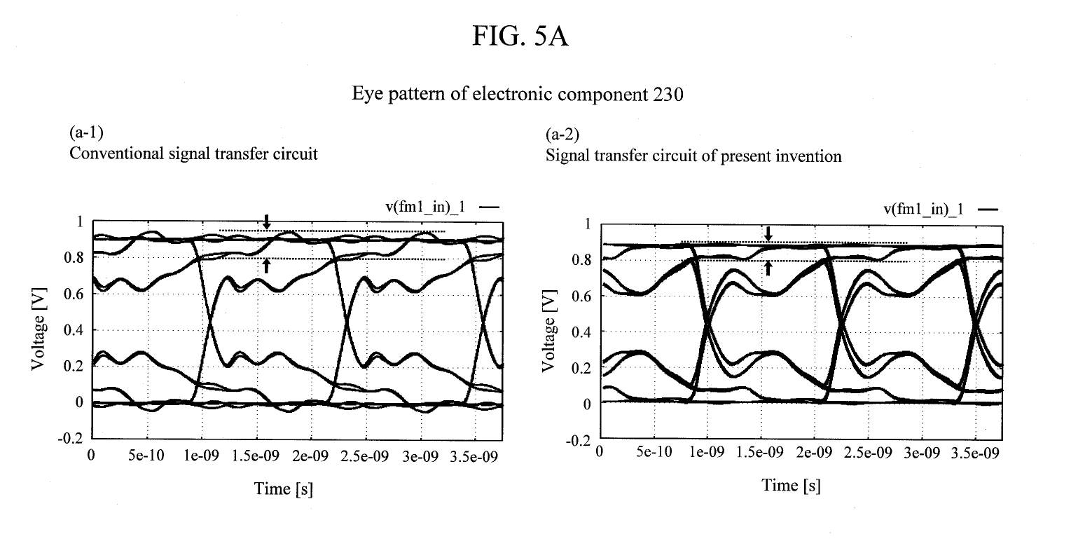

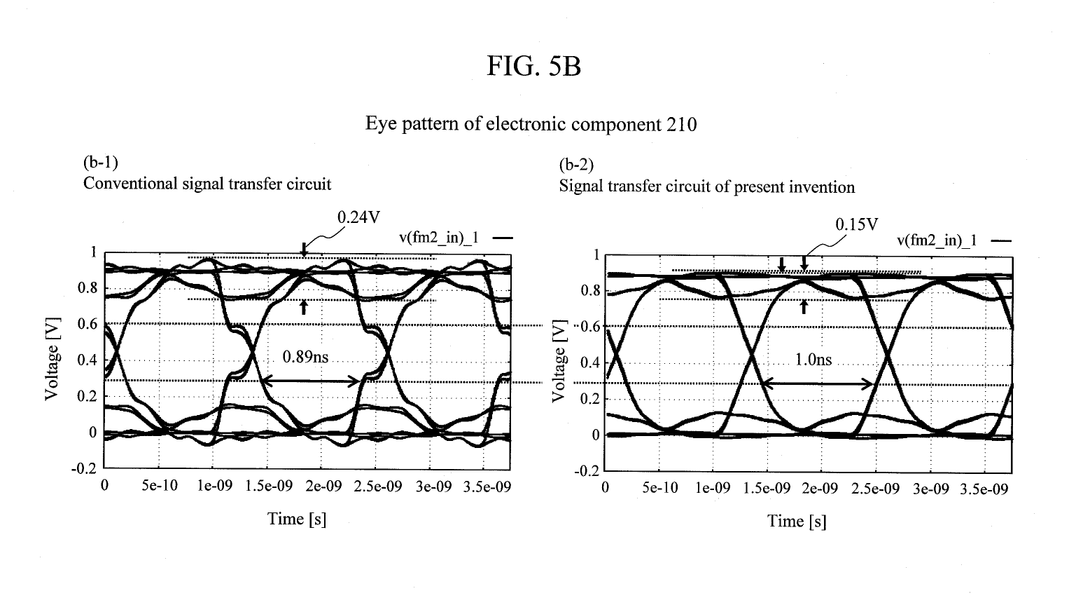

FIGS. 5A and 5B are diagrams showing the results of signal waveform analyses using the analysis models shown in FIGS. 4A and 4B. FIG. 5A shows the eye pattern of each electronic component 230 while FIG. 5B shows the eye pattern of each electronic component 210. The left diagrams show the eye patterns of the conventional signal transfer circuit while the right diagrams show the eye patterns of the signal transfer circuit 10 of Embodiment 1. The signal transfer rate is 800 Mbps, the characteristic impedance of each of the signal lines 401, 403, and 404 is 50Ω, and that of the resistor 251 is 50Ω. As shown in FIGS. 5A and 5B, the noises are smaller and the effective window widths of the signals are larger in the signal transfer circuit 10 of Embodiment 1.

### Embodiment 1

### Summary

As described above, in the signal transfer circuit 10 of Embodiment 1, the through-hole vias 111 and 112 are each so configured as to allow no branching from the middle thereof, and the electronic components and the through-hole vias are connected to each other through the surface wirings only. Accordingly, the signal paths are prevented from branching off from the middle of the through-hole vias, preventing the formation of stubs.

Moreover, in the signal transfer circuit 10 of Embodiment 1, the surface wirings are collected at the mounting surface of the board 100 without any signal path branching off from the middle of the through-hole vias, and signals are transmitted through the surface wirings by interleaved transmission. Accordingly, surface wirings can be mounted highly densely, and at the same time the crosstalk noise can be reduced.

Furthermore, in the signal transfer circuit 10 of Embodiment 1, the surface wirings 131 and 132 are arranged alternately, and the signal transmission circuit 300 transmits signals through these surface wirings by interleaved transmission. Since the wirings through which signals are transmitted simultaneously have a large gap therebetween and also shielding wires are introduced, the crosstalk noise can be reduced more effectively, together with the effect of the interleaved transmission.

### Embodiment 2

In Embodiment 1, the surface wirings 132 are extended between the lead terminals to arrange alternately the surface wirings 131 and 132. This arrangement will have no problem if the gap between the lead terminals is sufficiently large. However, a problem arises if the gap between the lead terminals is not sufficiently large as compared to the widths of the surface wirings, due to limitations given by the process of forming the wirings. To solve this, in Embodiment 2 of the present invention, the surface wirings 132 are arranged to avoid the electronic component 230.

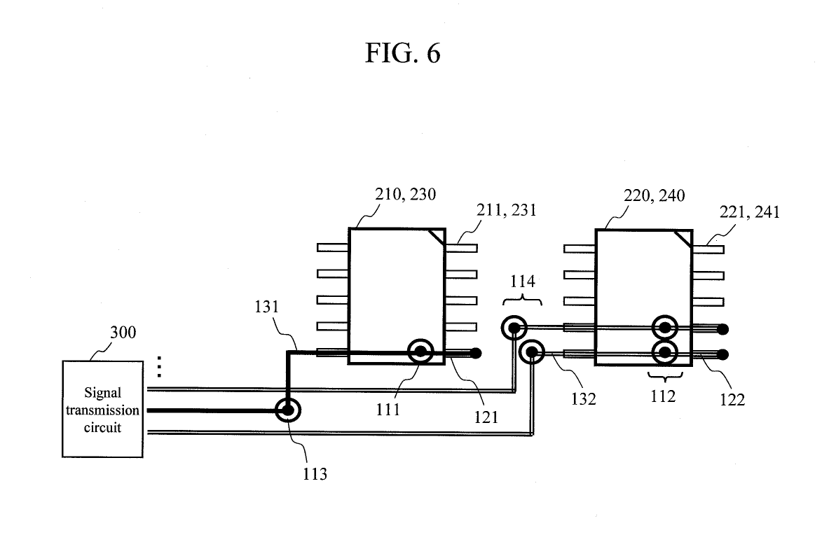

FIG. 6 is a transparent top view of a signal transfer circuit 10 of Embodiment 2. In Embodiment 2, surface wirings 132 are arranged to avoid an electronic component 230.

Surface wirings 131 do not necessarily have to follow the arrangement of the surface wirings 132. It is, however, desirable to alternately arrange the surface wirings 131 and 132 as much as possible, from the viewpoint of increasing the wiring density. Thus, in Embodiment 2, the surface wirings 131 are extended toward the arranged positions of the surface wirings 132, and both wirings are arranged alternately from positions where they meet.

However, to prevent the surface wirings 131 and 132 from crossing each other, additional through-hole vias 113 and 114 are provided to extend the wirings to the front surface of the board 100, so that the surface wirings 131 and 132 are alternately arranged only in a region on the left side of the through-hole vias 113 in FIG. 6.

In the configuration shown in FIG. 6, the surface wirings 131 and 132 are alternately arranged in a region on the left side of the through-hole vias 113, and thus the effect of the interleaved transmission can be exhibited in this region.

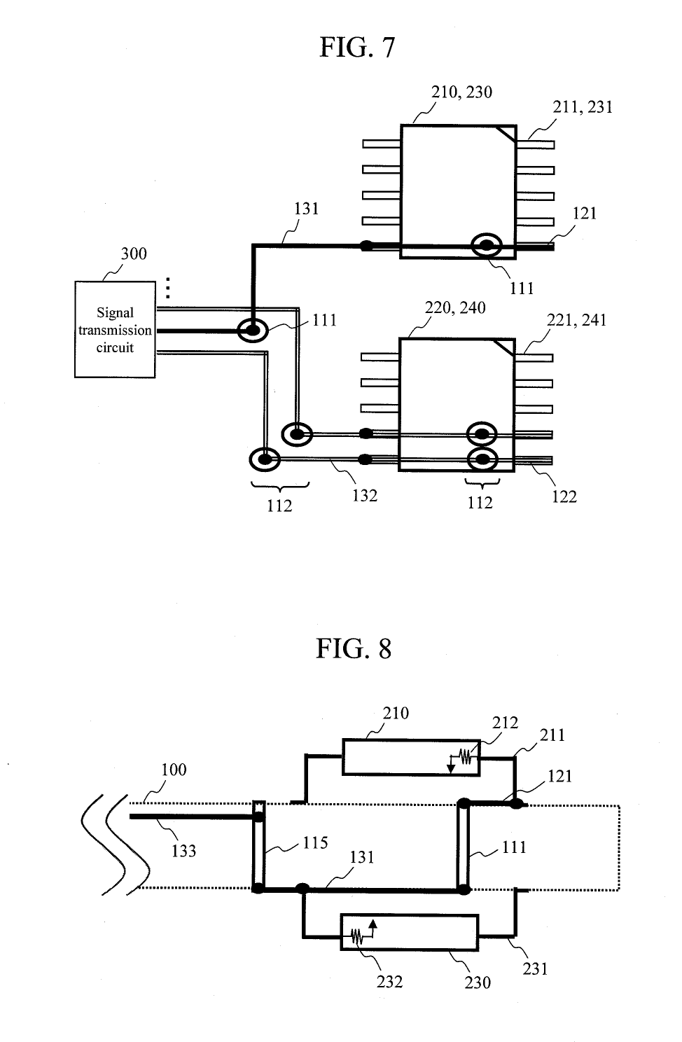

FIG. 7 is a transparent top view showing another example configuration of the signal transfer circuit 10 of Embodiment 2. In the configuration shown in FIG. 7, electronic components 210 and 220 are arranged adjacent to each other in a direction traversing a direction toward a signal transmission circuit 300, and so are the electronic components 230 and 240.

In the configuration shown in FIG. 7, the surface wirings 132 are arranged to avoid the electronic components 210 and 230, so that the same effect as that of FIG. 6 can be exhibited. Furthermore, the signal lines from the signal transmission circuit 300 to the electronic components 220 and 240 are made shorter. As a result, the section where the interleaved transmission is not performed is made shorter than that of FIG. 6, thus allowing more stable signal transmission.

### Embodiment 3

Embodiment 3 of the present invention will describe a case where part of each of the surface wirings 131 or 132 is configured as an internal wiring due to such a reason that it is impossible to secure a mounting space large enough to form the whole part of the wiring as a surface wiring.

FIG. 8 is a cross-sectional side view of a signal transfer circuit 10 of Embodiment 3. The configuration of the signal transfer circuit 10 of Embodiment 3 is substantially the same as the configurations described in Embodiments 1 and 2 but differs in that part of each of the surface wirings 131 is formed as an internal wiring 133 buried in the board 100. The surface wirings 132 can be arranged in the same fashion, though the description thereof will be omitted.

In FIG. 8, part of each of the surface wirings 131 in a section between the signal transmission circuit 300 and the electronic component 230 serves as the internal wiring 133. The internal wirings 133 and the surface wirings 131 are connected to each other by through-hole vias 115, respectively. The through-hole vias 115 and the internal wirings 133 create branching paths, forming stubs. To minimize the influence of the stubs, the internal wirings 133 are desirably arranged as close as possible to the front surface of the board 100.

In the configuration shown in FIG. 8, part of each of the surface wirings 131 is formed as the internal wiring 133. Accordingly, the configuration of Embodiment 3 can exhibit the substantially same effect as those of Embodiments 1 and 2, and at the same time, reduce the areas to amount the surface wirings 131. Moreover, the effect of the configuration of Embodiment 3 can be made closer to those of Embodiments 1 and 2 by minimizing the lengths of the stubs generated by the through-hole vias 115 and the internal wirings 133.

### Embodiment 4

Embodiment 4 of the present invention will describe a configuration for a case where the electronic components are mounted only on the front surface of the board 100.

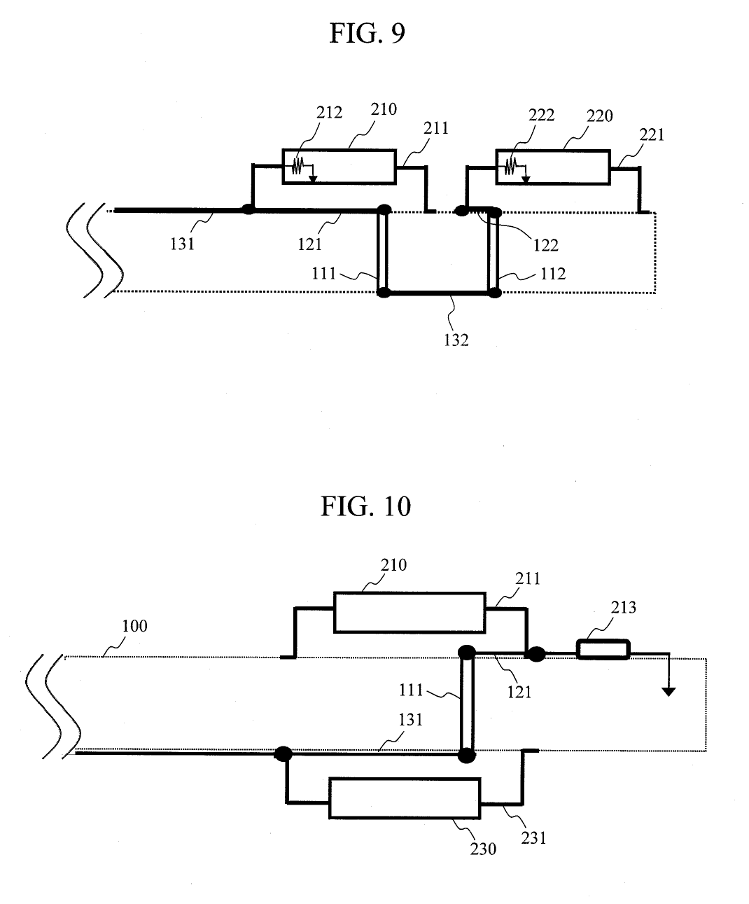

FIG. 9 is a cross-sectional side view of a signal transfer circuit 10 of Embodiment 4. In Embodiment 4, electronic components 210 and 220 are mounted only on the front surface of a board 100 and are configured to receive the same signal from a signal transmission circuit 300.

In FIG. 9, the electronic component 220 is arranged at a far side as seen from the signal transmission circuit 300. For this reason, signal lines from the signal transmission circuit 300 to the electronic component 220 need to avoid the electronic component 210 by, for example, running around the electronic component 210 or extending between lead terminals 11 of the electronic component 210.

However, any of these methods may not be employed due to an issue related to mounting area or the like. In such a case, as shown in FIG. 9, surface wirings 131 may be extended to the back surface of the board 100 through the through-hole vias 111, and signals may be transmitted to the electronic component 220 through surface wirings 132 on the back surface, through-hole vias 112, and surface wirings 122 on the front surface. As for the interleaved transmission of signals by the signal transmission circuit 300, Embodiment 4 is the same as Embodiments 1 to 3.

As described above, in the signal transfer circuit 10 of Embodiment 4, the surface wirings can avoid the electronic component through the through-hole vias even when it is difficult to extend the surface wirings between the lead terminals. As for the configuration allowing no branching point on the through-hole vias 111 and 122, the signal transfer circuit 10 of Embodiment 4 is the same as Embodiments 1 to 3 and therefore can exhibit the same effect.

### Embodiment 5

FIG. 10 is a cross-sectional side view of a signal transfer circuit 10 of Embodiment 5 of the present invention. In Embodiment 5, the electronic component 210 does not include the termination resistors 212 therein. Instead, external termination resistors 213 are provided and connected to the lead terminals 211, respectively. The other parts of the configuration are the same as those of Embodiments 1 to 4. Note that FIG. 10 assumes a configuration similar to that of Embodiment 1.

The signal transfer circuit 10 of Embodiment 5 can also exhibit the same effect as those of Embodiments 1 to 4.

### Embodiment 6

Embodiment 6 of the present invention will describe a specific example of the signal transmission circuit 300. The other parts of the configuration are the same as those of Embodiments 1 to 5. In the following, the description will be given while assuming the configuration described in Embodiment 1.

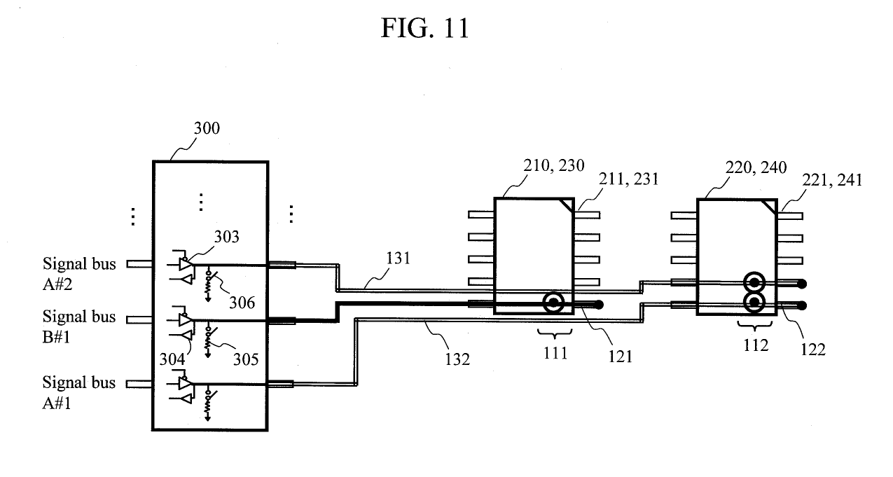

FIG. 11 is a diagram showing an example configuration of a signal transmission circuit 300 of Embodiment 6. The signal transmission circuit 300 includes sets of a transmitter 303, a receiver 304, a resistive element 305, and a switch 306.

While the switch 306 is OFF, a signal transmitted by the transmitter 303 is transmitted to the electronic component through the surface wiring 131 or 132. While the switch 306 is ON, the signal line is terminated through the resistive element 305. The resistance value of the resistive element 305 is desirably matched to the characteristic impedance of the wiring on the board.

The impedance matching of the resistance value of the resistive element 305 prevents the occurrence of signal reflection at the resistive element 305 even when a crosstalk noise is generated in unused signal lines during the interleaved transmission, and the noise is released to the ground. Accordingly, a crosstalk noise between the signal lines used in the interleaved transmission can be reduced.

### Embodiment 7

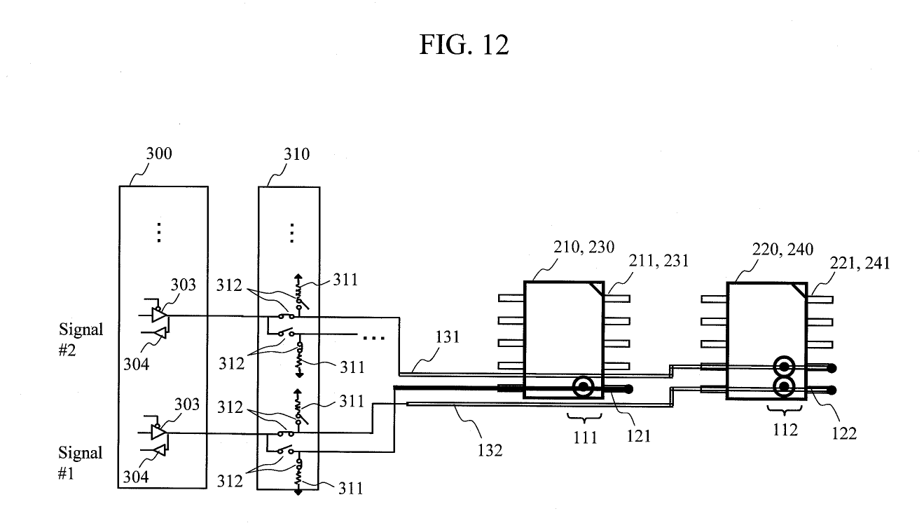

FIG. 12 is a configuration diagram of a signal transfer circuit 10 of Embodiment 7 of the present invention. The configuration of the signal transfer circuit 10 of Embodiment 7 is the same as that of Embodiment 6 except the configuration of the signal transmission circuit 300.

In Embodiment 7, a signal transmission circuit 300 includes sets of a transmitter 303 and a receiver 304, as well as a bus switch 310. The transmitter 303 and the receiver 304 are the same as those of Embodiment 6. The bus switch 310 includes sets of resistive elements 311 and switches 312.

While the switch 312 connected to the surface wiring 131 or 132 is ON, a signal transmitted by the transmitter 303 is transmitted to the electronic element through the surface wiring. While the switch 312 connected to the resistive element 311 is ON, the switch 312 connected to the surface wiring 131 or 132 is OFF, and the signal line is terminated through the resistive element 312.

By adding the bus switch 310, Embodiment 7 can exhibit the same effect as those of Embodiments 1 to 6 even when the signal transmission circuit 300 itself has no interleaved transmission function.

The present invention is not limited to the embodiments described above but includes various modifications. For example, each embodiment given above is described in detail for the purpose of explaining the present invention in simple ways, and the present invention is not necessarily limited to those including every part of the configuration described above. In addition, part of the configuration in one embodiment may be replaced with part of the configuration in a different embodiment. Moreover, part of the configuration in one embodiment may be added to the configuration in a different embodiment. Furthermore, for part of the configuration in each embodiment, part of a different configuration may be added, removed, or replaced.

Moreover, in each configuration described above, part or all of it may be given a multi-stage configuration to improve the performance. For example, semiconductor elements to be connected may be multi-staged for increase in the number of signal buses.

Moreover, the signal lines and the elements of components are described as ones considered necessary in the explanation, but not all the signal lines and the elements of components in a product may be described. It is conceivable that the topology of the signal lines linking the components and the number of the elements of components are in a plural configuration in the actual case.

### EXPLANATION OF REFERENCE NUMERALS

100 . . . board, 111 to 115 . . . through-hole via, 1111 . . . stub, 121, 122, 131, 132 . . . surface wiring, 133, 141 . . . internal wiring, 210, 220, 230, 240 . . . electronic component, 211, 221, 231, 241 . . . lead terminal, 250 . . . receiving circuit, 212, 222, 232, 251 . . . resistor, 252 . . . capacitor, 300 . . . signal transmission circuit, 301 . . . resistor, 302 . . . waveform generator, 303 . . . transmitter, 304 . . . receiver, 305 . . . resistive element, 306 . . . switch, 310 . . . bus switch, 311 . . . resistive element, 312 . . . switch, 401, 403, 404 . . . signal line, 402 . . . inductor

What is claimed is:

1. A signal transfer circuit comprising:
a board on which a first electronic component and a second electronic component are mounted;
vias penetrating through the board;
a transmission circuit configured to transmit signals to the first electronic component and the second electronic component;
first wirings connecting the first electronic component to the transmission circuit; and
second wirings connecting the second electronic component to the transmission circuit, wherein
the vias electrically connected to the first electronic component and the vias electrically connected to the second electronic component are each configured so that those vias don't branch off inside the board and that each of the branched path of those vias is not electrically connected with different electronic components from each other,
lead terminals of the first electronic component and lead terminals of the second electronic component are connected to the vias solely through surface wirings on the board, respectively,
the first wirings are each arranged between a corresponding pair of the second wirings, and
the transmission circuit transmits the signals through the first wirings and the second wirings by interleaved transmission.

2. The signal transfer circuit according to claim 1, wherein the second wirings are each arranged between a corresponding pair of the lead terminals of the first electronic component.

3. The signal transfer circuit according to claim 1, wherein the second wrings are arranged to avoid the first electronic component.

4. The signal transfer circuit according to claim 3, wherein the first electronic component and the second electronic component are arranged adjacent to each other in a direction traversing a direction toward a position where the transmission circuit is arranged.

5. The signal transfer circuit according to claim 1, wherein any one of part of each of the first wirings and part of each of the second wirings is configured as an internal wiring inside the board.

6. The signal transfer circuit according to claim 1, further comprising external termination resistors connected to the lead terminals of any one of the first electronic component and the second electronic component, respectively.

7. The signal transfer circuit according to claim 1, wherein
the transmission circuit includes:
switches configured to switch between transmission and blocking of the signals to the first wirings and the second wirings, respectively; and
termination resistors terminating the first wirings and the second wirings, respectively, wherein
the termination resistors are configured to have resistance values matching characteristic impedances of the first wirings and characteristic impedances of the second wirings.
